(19) United States
(12) Patent Application Publication
(10) Pub. No.: US 2012/0248939 A1
(43) Pub. Date: Oct. 4, 2012

(54) METHOD OF MANUFACTURING PIEZOELECTRIC VIBRATOR, PIEZOELECTRIC VIBRATOR, OSCILLATOR, ELECTRONIC DEVICE, AND RADIO WATCH

(76) Inventor: Yoichi Funabiki, Chiba-shi (JP)

(21) Appl. No.: 13/432,429

(22) Filed: Mar. 28, 2012

(30) Foreign Application Priority Data
Mar. 29, 2011 (JP) 2011-071422

(51) Int. Cl. H01L 41/053; H01L 41/22

(52) U.S. Cl. 310/348; 29/25.35

(57) ABSTRACT

The present invention reduces the value of a bonding width L of a base substrate and a lid substrate in each piezoelectric vibrator. A plurality of lid substrates 3 each including a recess portion 3a are formed and a bonding film is formed on a wafer for lid substrate 50. The wafer for base substrate 40 is opposed and anodic-bonded to the wafer for lid substrate 50 to produce a wafer unit 60 including a plurality of piezoelectric vibrators 1. Then, a microgroove 813 is formed by applying laser along a cutting line for each of the piezoelectric vibrators 1 on the side of the wafer for lid substrate 50, and a sharp pressing blade 830 is pressed on the opposite side, thereby performing sequential cutting.

### RELATED APPLICATIONS

This application claims priority under 35 U.S.C. §119 to Japanese Patent Application No. 2011-071422 filed on Mar. 29, 2011, the entire content of which is hereby incorporated by reference.

### BACKGROUND OF THE INVENTION

1. Field of the Invention

The present invention relates to a method of manufacturing a piezoelectric vibrator, a piezoelectric vibrator, an oscillator, an electronic device, and a radio watch.

2. Description of Related Art

In recent years, cellular phones and portable information terminal devices have employed a piezoelectric vibrator using a crystal or the like as a time source, a timing source for a control signal or the like, a reference signal source or the like.

The piezoelectric vibrator includes a base substrate and a lid substrate bonded together and a piezoelectric vibrating strip enclosed within a cavity (hollow portion) C formed between the substrates.

For manufacturing such piezoelectric vibrators, the piezoelectric vibrators are not manufactured individually but a series of piezoelectric vibrators is manufactured and then cut into individual piezoelectric vibrators to enhance mass-producibility.

Specifically, as shown in FIG. 19, a piezoelectric vibrator-group wafer 400 is formed which includes a wafer for base substrate and a wafer for lid substrate having a plurality of base substrates and a plurality of lid substrates formed thereon, respectively. Then, the wafer 400 is cut along cutting lines M (imaginary lines) indicated by dotted lines to manufacture respective piezoelectric vibrators.

JP-A-2009-88621 has described a method of cutting the piezoelectric vibrator-group wafer 400 with a glass substrate through the use of a blade.

As shown in FIGS. 19 and 20, however, for cutting into individual piezoelectric vibrators 200 with the blade, a cutting margin of 150 μm to 200 μm is needed for the thickness of a blade 300. This reduces the number of obtained chips (piezoelectric vibratos) or requires that the wafer for base substrate and the wafer for lid substrate should be increased in size.

In addition, cracks 209 occur in the cutting faces due to vibrations and shocks during the cutting with the blade 300. Furthermore, the width (L in FIG. 20) of a bonding face needs to be increased to provide a sufficient strength so that the bonding of a base substrate 201 and a lid substrate 202 can withstand the vibrations and shocks. A bonding width of 200 μm or more has conventionally been required.

The increase in the width L of the bonding face causes the problems in which the cavity C of each piezoelectric element is shrunk or the wafer size should be increased.

The present invention has been made in view of the circumstances described above, and it is an object thereof to reduce the size of a cutting margin in a wafer unit provided by bonding a base substrate to a lid substrate for piezoelectric vibrators.

### SUMMARY OF THE INVENTION

To achieve the above object, the present invention provides a method of manufacturing a plurality of piezoelectric vibrators by using a wafer for base substrate and a wafer for lid substrate, a piezoelectric vibrating strip being enclosed within a cavity formed between a base substrate and a lid substrate bonded together in the piezoelectric vibrator, including a bonding step of housing the piezoelectric vibrating strip in the cavity to bond the wafer for base substrate and the wafer for lid substrate to form a wafer unit, and a cutting step of cutting and singulating the wafer unit into a plurality of the piezoelectric vibrators, wherein the cutting step includes a step of forming a plurality of microgrooves along a cutting line in an outer face on the side of the wafer for base substrate or in an outer face on the side of the wafer for lid substrate, and a break step of pressing the wafer unit on the side opposite to the side of the wafer unit having the microgroove formed therein to split the wafer unit along the microgroove.

According to the present invention, a cutting margin in a wafer unit provided by bonding a base substrate to a lid substrate for each piezoelectric vibrator can be reduced.

### BRIEF DESCRIPTION OF THE DRAWINGS

FIG. 1 is a perspective view showing the outer appearance of an embodiment of a piezoelectric vibrator according to the present invention.

FIG. 2 is a diagram showing the internal configuration of the piezoelectric vibrator shown in FIG. 1.

FIG. 3 is a section view of the piezoelectric vibrator taken along a line A-A shown in FIG. 2.

FIG. 4 is an exploded perspective view of the piezoelectric vibrator shown in FIG. 1.

FIG. 5 is a top view of a piezoelectric vibrating strip shown in FIG. 1.

FIG. 6 is a bottom view of the piezoelectric vibrating strip shown in FIG. 5.

FIG. 7 is a section view from an arrow B-B shown in FIG. 5.

FIG. 8 is a flow chart showing the flow in manufacturing the piezoelectric vibrator shown in FIG. 1.

FIG. 9 is a diagram showing a step in manufacturing the piezoelectric vibrator with the flow chart shown in FIG. 8.

FIG. 10 is a diagram showing a step in manufacturing the piezoelectric vibrator with the flow chart shown in FIG. 8.

FIG. 11 is a diagram showing the overall wafer for base substrate shown in FIG. 10.

FIG. 12 is a diagram showing a step in manufacturing the piezoelectric vibrator with the flow chart shown in FIG. 8.

FIG. 13 is a diagram showing a step in manufacturing the piezoelectric vibrator with the flow chart shown in FIG. 8.

FIGS. 14A-14C are diagrams showing a step in manufacturing the piezoelectric vibrator with the flow chart shown in FIG. 8.

FIG. 15 is a diagram for explaining the order of cutting at a cutting step.

FIG. 16 is a schematic diagram showing an example of an oscillator according to the present invention.

FIG. 17 is a schematic diagram showing an example of an electronic device according to the present invention.

FIG. 18 is a schematic diagram showing an example of a radio watch according to the present invention.

FIG. 19 is a diagram showing a conventional wafer on which a plurality of piezoelectric vibrators are formed.

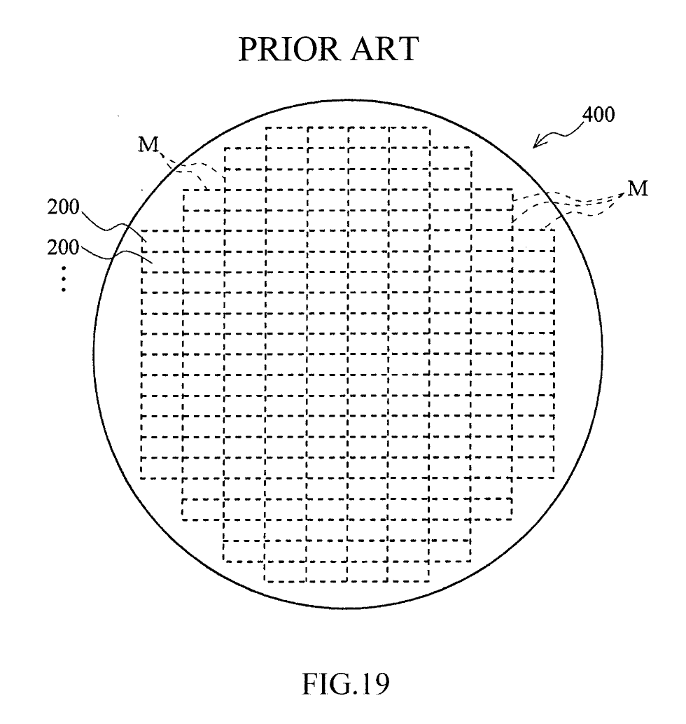

FIG. 20 is a section view showing the conventional wafer under cutting.

### DETAILED DESCRIPTION OF THE PREFERRED EMBODIMENTS

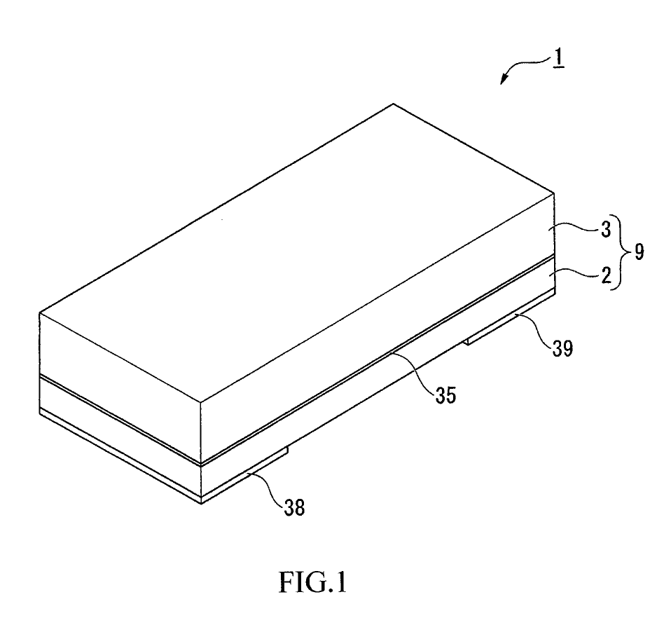

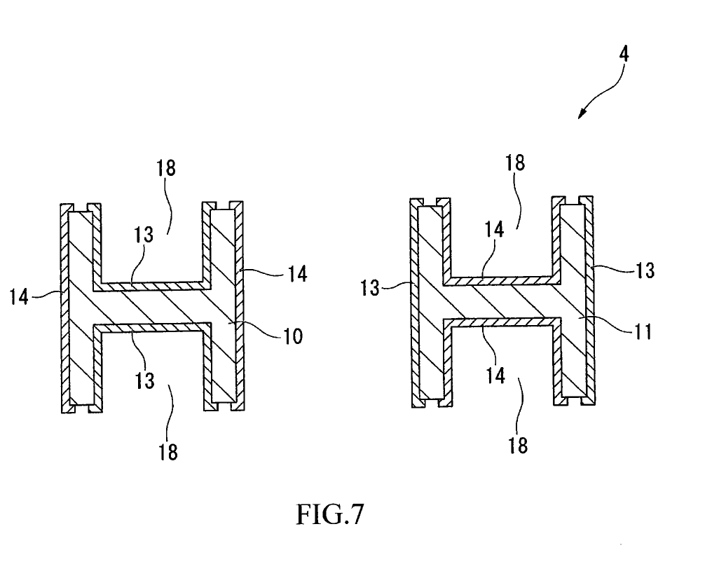

A preferred embodiment of the present invention will hereinafter be described with reference to FIG. 1 to FIG. 18 by taking examples of a method of manufacturing a piezoelectric vibrator, a piezoelectric vibrator manufactured by the manufacture method, an oscillator, an electronic device, and a radio watch having the piezoelectric vibrator.

### (1) Outlines of Embodiment

The manufacture of a piezoelectric vibrator 1 starts with formation of a wafer for base substrate 40 and a wafer for lid substrate 50 made of a glass material, for example soda-lime glass. The wafer for base substrate 40 has a plurality of base substrate 2 formed thereon each including two through electrodes 7. The wafer for lid substrate 50 has a plurality of lid substrates 3 formed thereon in association with each of the base substrates 2, and each of the lid substrates 3 includes a recess portion 3a for forming a cavity C. The wafer for lid substrate 50 has a bonding film 35 formed on the side of the recess portion 3a.

A piezoelectric vibrating strip 4 is mounted on each of the base substrates 2 of the wafer for base substrate 40. The wafer for base substrate 40 and the wafer for lid substrate 50 are opposed to each other such that the piezoelectric vibrating strip 4 is placed within the cavity C formed by the recess portion 3a and then the wafers are anodic-bonded, thereby providing a wafer unit 60 including the plurality of piezoelectric vibrators 1.

Then, the side of the wafer for lid substrate 50 is irradiated with laser along cutting lines for respective piezoelectric vibrators 1 to produce microgrooves.

A pressing blade 832 having a sharp end is used to push the side opposite to the microgrooves, that is, the side of the wafer for base substrate 40, at the position associated with the microgroove to perform cutting sequentially. The pressing of the microgrooves from the opposite side can split the wafer unit 60 favorably.

The cutting with the pressing blade 832 is performed sequentially along a longitudinal direction of the piezoelectric vibrators 1, and after the completion of the cutting in the vertical direction, the cutting is performed sequentially along cutting lines in a lateral direction of the piezoelectric vibrators 1.

### (2) Details of Embodiment

FIG. 1 to FIG. 4 shows the structure of the piezoelectric vibrator 1.

As shown in these figures, the piezoelectric vibrator 1 is mainly formed of the base substrate 2, the lid substrate 3, and the piezoelectric vibrating strip 4.

The piezoelectric vibrator 1 is of an SMD (Surface Mount Device) type including a package 9 having the base substrate 2 and the lid substrate 3 put one on another to form the cavity C between them, and the piezoelectric vibrating strip 4 housed within the cavity C and electrically connected to routing electrodes (internal electrodes) 36 and 37.

While the cavity C is provided by forming the recess portion 3a on the side of the lid substrate 3 in the present embodiment shown, the cavity C may be provided by forming a recess portion on the side of the base substrate 2 or by forming a recess portion in each of the base substrate 2 and the lid substrate 3.

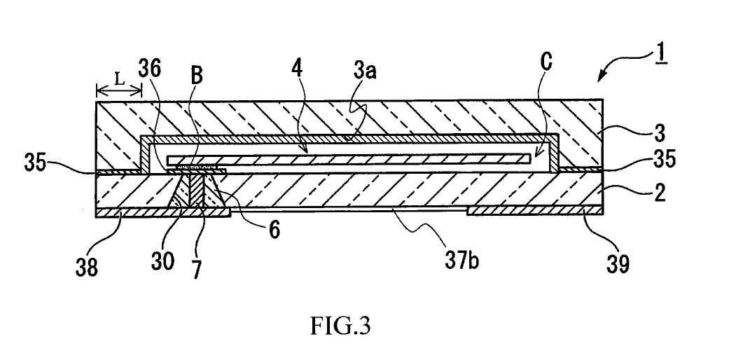

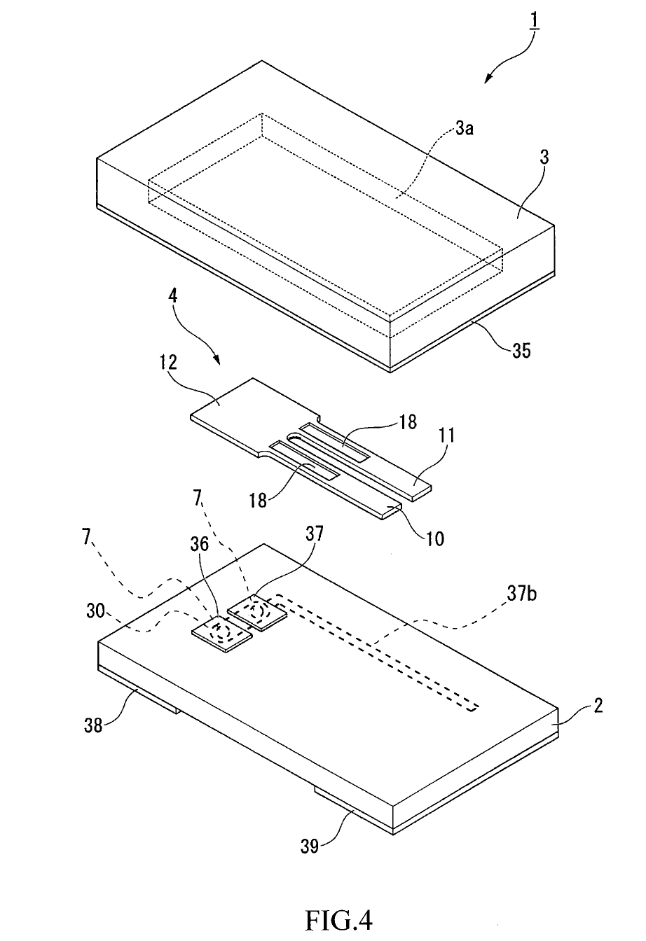

In FIG. 3 and FIG. 4, an exciting electrode 15 for the piezoelectric vibrating strip 4, lead electrode 19 and 20, mount electrodes 16 and 17, and a weight metal film 21 are omitted for clarity of the drawings.

### (3) Piezoelectric Vibrating Strip

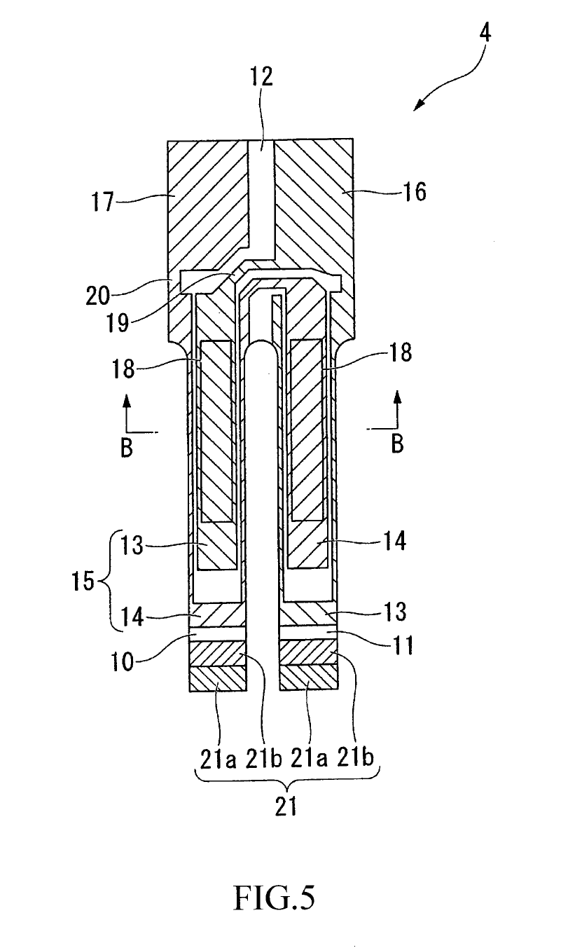

As shown in FIG. 5 to FIG. 7, the piezoelectric vibrating strip 4 is a tuning fork-type vibrating strip made of a piezoelectric material such as crystal, lithium tantalate, and lithium niobate, and vibrates in response to application of a predetermined voltage. The piezoelectric vibrating strip 4 has a pair of vibrating arm portions 10 and 11 placed in parallel, a base portion 12 integrally fixing the pair of vibrating arm portions 10 and 11 at their base ends, the exciting electrode 15 consisting of a first exciting electrode 13 and a second exciting electrode 14 formed on each of outer faces of the pair of vibrating arm portions 10 and 11 at their base ends to vibrate the pair of vibrating arm portions 10 and 11, and the mount electrodes 16 and 17 electrically connected to the first exciting electrode 13 and the second exciting electrode 14. The piezoelectric vibrating strip 4 also has a groove portion 18 formed on each of main faces of the pair of vibrating arm portions 10 and 11 along the longitudinal direction of the vibrating arm portions 10 and 11. The groove portion 18 is formed from the base end of the vibrating arm portions 10 and 11 to near a generally intermediate portion.

The piezoelectric vibrating strip 4 is a known tuning fork-type vibrating strip made of a piezoelectric material such as crystal, lithium tantalate, and lithium niobate, and vibrates in response to application of a predetermined voltage.

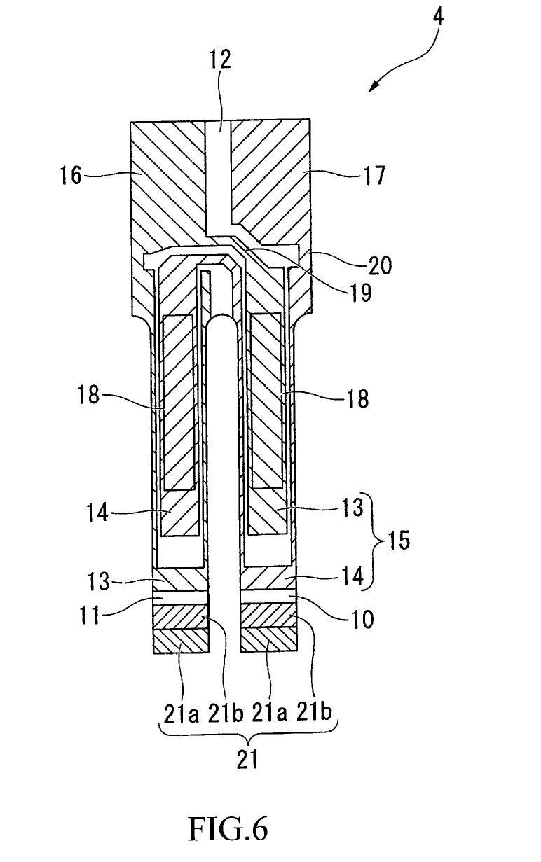

As shown in FIGS. 5 and 6, the piezoelectric vibrating strip 4 has the pair of vibrating arm portions 10 and 11 placed in parallel, the base portion 12 integrally fixing the vibrating arm portions 10 and 11 at their base ends, the exciting electrode 15 consisting of the first exciting electrode 13 and the second exciting electrode 14 formed on each of the outer faces of the vibrating arm portions 10 and 11 at their base ends to vibrate the pair of vibrating arm portions 10 and 11, and the mount electrodes 16 and 17 electrically connected to the first exciting electrode 13 and the second exciting electrode 14.

The piezoelectric vibrating strip 4 according to the present embodiment also has the groove portion 18 formed on each of the main faces of the pair of vibrating arm portions 10 and 11 along the longitudinal direction of the vibrating arm portions 10 and 11. The groove portion 18 is formed from each of the base end of the vibrating arm portions 10 and 11 to near the generally intermediate portion.

The exciting electrode 15 consisting of the first exciting electrode 13 and the second exciting electrode 14 is an electrode for vibrating the pair of vibrating arm portions 10 and 11 at a predetermined resonance frequency in directions in which they are brought closer to or away from each other, and is formed through patterning on each of the outer faces of the pair of vibrating arm portions 10 and 11 such that the exciting electrode 13 and 14 are electrically isolated from each other. Specifically, the first exciting electrodes 13 is formed mainly on the groove portion 18 of one vibrating arm portion 10 and on both side faces of the other vibrating arm portion 11, and the second exciting electrodes 14 is formed on both side faces of the one vibrating arm portion 10 and on the groove portion 18 of the other vibrating arm portion 11.

The first exciting electrode 13 and the second exciting electrode 14 are electrically connected to the mount electrodes 16 and 17 through the lead electrode 19 and 20 on the main faces of the base portions 12. A voltage is applied to the piezoelectric vibrating strip 4 through the mount electrodes 16 and 17.

Each of the exciting electrode 15, the mount electrodes 16 and 17, and the lead electrode 19 and 20 described above is formed of a conductive film made of chromium (Ch), nickel (Ni), aluminum (Al), titanium (Ti) or the like, for example.

The weight metal film 21 is deposited on each of tips of the pair of vibrating arm portions 10 and 11 for achieving mass adjustment (frequency adjustment) such that the portions 10 and 11 vibrate within a range of predetermined frequencies.

The weight metal film 21 is divided into a rough-adjustment film 21a used in roughly adjusting the frequency and a fine-adjustment film 21b used in fine adjustment. The rough-adjustment film 21a is formed on the side closer to the end portion of the vibrating arm portions 10 and 11 than the fine-adjustment film 21b.

The frequency adjustment is performed by using the rough-adjustment film 21a and the fine-adjustment film 21b to allow the frequency of the pair of vibrating arm portions 10 and 11 to fall within the range of nominal (target) frequencies of the device.

As shown in FIG. 3, the piezoelectric vibrating strip 4 formed in this manner is bonded to an upper face (face closer to the cavity C) of the base substrate 2 with a conductive adhesive.

Specifically, the routing electrodes 36 and 37 patterned (formed) on an inner face of the base substrate 2 (upper face, a bonding face to which the lid substrate 3 is bonded) are bump-bonded to the pair of mount electrodes 16 and 17 of the piezoelectric vibrating strip 4 respectively by using a bump B made of gold or the like.

This causes the piezoelectric vibrating strip 4 to be supported such that it is separate from the upper face of the base substrate 2 and that the mount electrodes 16 and 17 and the routing electrodes 36 and 37 are electrically connected to each other through the bump B.

The bump B is omitted in FIG. 4 for clarity of the drawings.

The vibrating arm portions 10 and 11 of the piezoelectric vibrating strip 4 are supported to be separate from the base substrate 2 by the bump B in the present embodiment. Alternatively, a recess portion may be formed in an area of the base substrate 2 associated with the vibrating arm portions 10 and 11 and the piezoelectric vibrating strip 4 may be supported such that the vibrating arm portions 10 and 11 are separate from the base substrate 2 in the recess portion.

### (4) Piezoelectric Vibrator

As shown in FIG. 1 to FIG. 4, the piezoelectric vibrator 1 of the present embodiment includes the package 9 provided by putting the base substrate 2 on the lid substrate 3 in two layers.

The base substrate 2 is a transparent insulating substrate made of a glass material, for example soda-lime glass, and is formed in a plate shape. The base substrate 2 of the present embodiment is formed to have a thickness of approximately 400 μm.

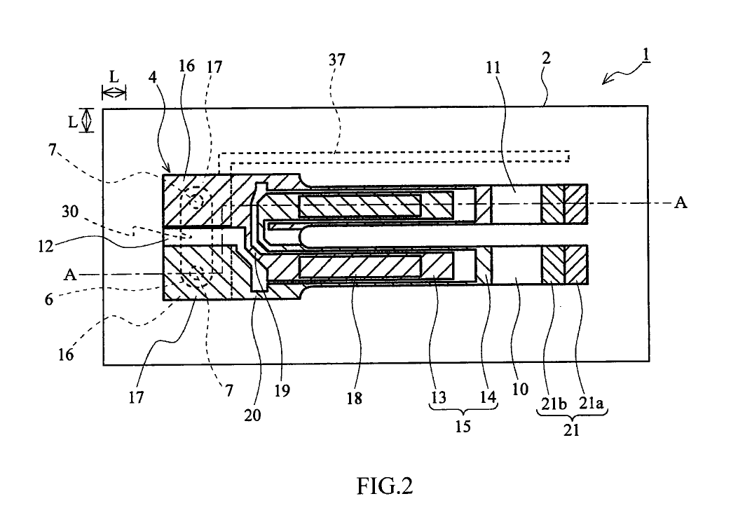

As shown in FIG. 2 and FIG. 3, the base substrate 2 has a through hole 30 formed therein which passes through the base substrate 2 in a thickness direction to be opened in the cavity C.

The through hole 30 is formed on the side where the base portion 12 of the piezoelectric vibrating strip 4 is placed. The through hole 30 has an oblong (or oval) shape to include at least part of the mount electrodes 16 and 17 formed on the base portion 12 closer to the base substrate 2. The through hole 30 is formed in a tapered shape to have a diameter gradually reduced from a lower face to an upper face (closer to the cavity C) of the base substrate 2.

The shape of the through hole is not limited thereto, and the through hole may have a cylindrical shape for example. In the present embodiment, the oblong shape of the through hole 30 can reduce the volume thereof to reduce the amount of low-melting point glass filed into the through hole 30.

An enclosing glass 6 and two through electrodes 7 and 7 electrically connecting the mount electrodes 16 and 17 to an external electrode are placed within the through hole 30 to fill the through hole 30. In other words, the two through electrodes 7 and 7 are provided for one through hole 30.

The enclosing glass 6 is formed by firing glass frit of paste form. The firing causes the through electrodes placed inside to be fixed and tightly secured to the through hole 30 and completely fills the through hole 30 to maintain hermeticity within the cavity C.

Each of the through holes 7 and 7 is a conductive core material formed of 42 alloy in a column shape, for example, and is formed to have a flat shape at both ends similarly to the seal glass 6 and to have substantially the same thickness as that of the base substrate 2.

An external electrode 38 to be electrically connected to one of the through electrodes 7 is formed on an outer face of the base substrate 2.

An external electrode 39 to be electrically connected to the other of the through electrodes 7 is formed on the outer face of the base substrate 2. The routing electrode 37b electrically connects the through electrode 7 to the external electrode 39.

As shown in FIG. 1, FIG. 3, and FIG. 4, the lid substrate 3 is a transparent insulating substrate made of a glass material similarly to the base substrate 2, for example soda-lime glass, and is formed in a plate shape having a size which can be put on the base substrate 2 as shown in FIG. 1 to FIG. 4.

The recess portion 3a having a rectangular shape for accommodating the piezoelectric vibrating strip 4 is formed in an inner face of the lid substrate 3. This recess portion 3a serves as the cavity C for accommodating the piezoelectric vibrating strip 4 when both substrates 2 and 3 are placed one on another. The lid substrate 3 is bonded to the base substrate 2 with the recess portion 3a opposite to the base substrate 2.

As shown in FIG. 1 to FIG. 4, the bonding film 35 is formed over the entire face of the lid substrate 3 opposite to the base substrate 2 in the present embodiment. The bonding film 35 is used to anodic-bond the base substrate 2 to the lid substrate 3. The bonding film 35 is formed of a material (for example, aluminum, silicon, chromium and the like) usable for anodic bonding.

While the present embodiment is described in conjunction with the case where the bonding film 35 is formed over the entire face of the lid substrate 3, the bonding film 35 may be formed only on the surface in contact with the lid substrate 3.

For operating the piezoelectric vibrator 1 formed in this manner, a predetermined driving voltage is applied to the external electrodes 38 and 39 formed on the base substrate 2. This can apply the voltage to the exciting electrode 15 formed of the first exciting electrode 13 and the second exciting electrode 14 of the piezoelectric vibrating strip 4 to vibrate the pair of the vibrating arm portions 10 and 11 at a predetermined frequency in directions in which they are brought closer to or away from each other. The vibration of the pair of the vibrating arm portions 10 and 11 can be used as a time source, a timing source for a control signal, a reference signal source or the like.

### (5) Method of Manufacturing Piezoelectric Vibrator

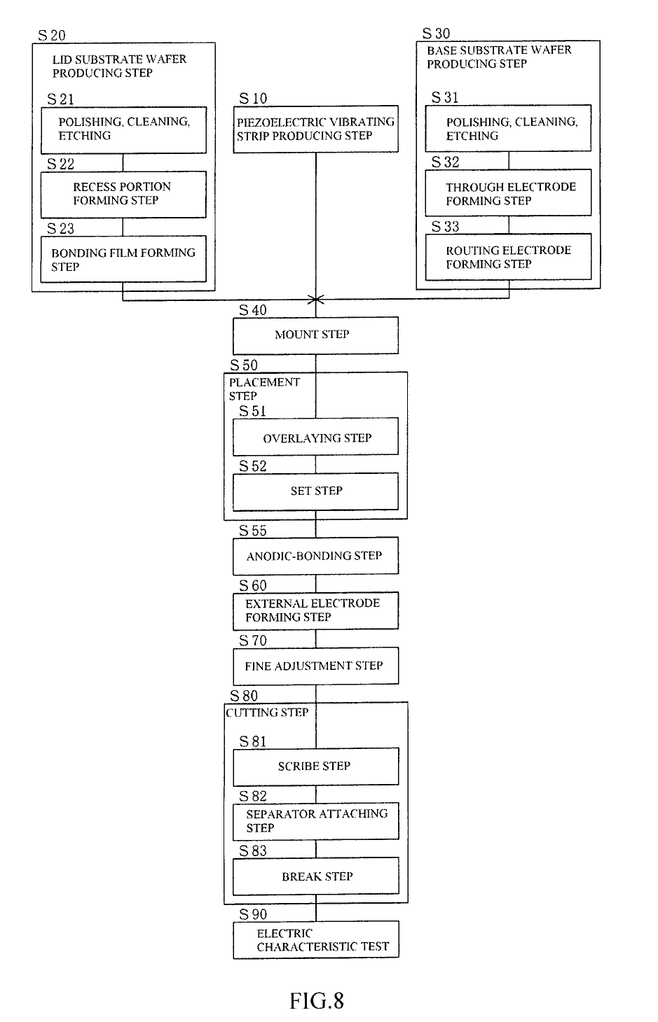

Next, description will be made of a method of manufacturing a plurality of piezoelectric vibrators 1 at a time by using the wafer for base substrate 40 and the wafer for lid substrate 50 with reference to FIG. 8.

While a plurality of piezoelectric vibrators 1 are manufactured at a time by using the substrate in wafer form in the present embodiment, the method of manufacturing the piezoelectric vibrator 1 is not limited thereto, and the present invention may provide a method of manufacturing one piezoelectric vibrator 1 by bonding a base substrate 2 and a lid substrate 3 which are previously singulated.

The manufacture of the plurality of piezoelectric vibrators 1 with the substrate in wafer form involves performing first a piezoelectric vibrating strip producing step (S10), a lid substrate wafer producing step (S20), and a base substrate wafer producing step (S30). The three steps may be performed in any order and may be performed simultaneously in parallel.

First, description is made of the piezoelectric vibrating strip producing step (S10) for producing the piezoelectric vibrating strip 4 with reference to FIG. 5 to FIG. 7.

First, a crystal lambert ore is sliced at a predetermined angle into a crystal wafer having a predetermined thickness.

Then, after the crystal wafer is subjected to lapping and rough processing, the processing altered layer is removed through etching, and mirror polishing is performed such as polishing to provide the crystal wafer having a predetermined thickness.

After the crystal wafer is cleaned, the wafer is patterned into the outer shape of the piezoelectric vibrating strip 4 with a photolithography technology to provide the outer shape of the piezoelectric vibrating strip 4. A metal film is deposited on the piezoelectric vibrating strip 4 having only the outer shape formed and is patterned to form the exciting electrode 15, the lead electrodes 19 and 20, the mount electrodes 16 and 17, and the weight metal film 21. This step can produce the piezoelectric vibrating strip.

After the piezoelectric vibrating strip 4 is produced, rough adjustment is performed for the resonance frequency. This is performed by applying laser light to the rough-adjustment film 21a of the weight metal film 21 to evaporate a portion thereof to change the weight.

Fine adjustment of adjusting the resonance frequency more accurately is performed after mounting of the piezoelectric vibrating strip 4 into the package. This is described later.

Next, the lid substrate wafer producing step (S20) is described. First, soda-lime glass is polished to a predetermined thickness, cleaned, and then, subjected to etching or the like to remove a processing altered layer on an outermost face to provide the discoid wafer for lid substrate 50 (S21).

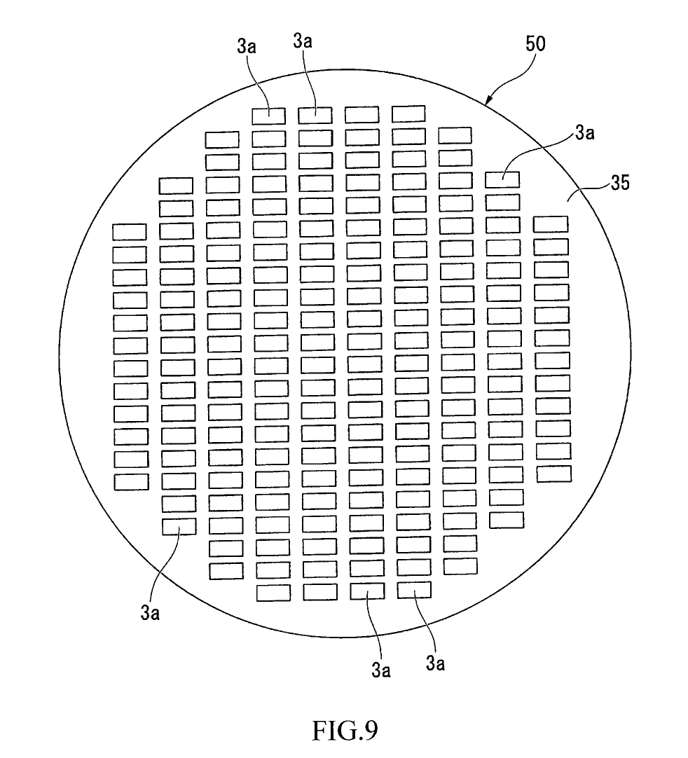

Next, as shown in FIG. 9, a plurality of recess portions 3a for the cavity C are formed through etching or debossing at a predetermined temperature or higher in the inner face of the wafer for lid substrate 50 (S22).

This recess portion forming step may be performed by heating a mold to a softening point or higher of the wafer for lid substrate 50 and pressing the mold against the wafer for lid substrate 50, similarly to the step of forming the through hole in the base substrate 2.

Next, a bonding film forming step (S23) is performed in which the bonding film 35 is formed over the entire region of the wafer for lid substrate 50 on the inner face side where the recess portions 3a are formed. The bonding film 35 is formed through evaporation or sputtering. Then, the lid substrate wafer producing step (S20) is ended.

Next, the base substrate wafer producing step (second wafer producing step) (S30) is described. First, soda-lime glass is polished to a predetermined thickness, cleaned, and then, subjected to etching or the like to remove a processing altered layer on an outermost face to provide the discoid wafer for base substrate 40 (S31).

Then, a through electrode forming step (S32) is performed in which a plurality of the pair of through electrodes 7 and 7 are formed in the wafer for base substrate 40.

First, the through holes 30 are formed in the areas formed in the wafer for base substrate 40 that are associated with the respective cavities C. The single through hole 30 may be formed in the single area associated with each of the cavities C. The through hole 30 may be formed with a sandblast method, pressing or the like.

A pair of through electrodes 7 and 7 is placed in the single through hole 30. Then, powder glass (low-melting point glass) is filled into the through hole 30 and fired to enclose the through hole 30 and to fix the through electrodes 7 and 7 within the through hole 30. Then, the surface of the base substrate 2 is polished such that the end faces of the through electrodes 7 and 7 are exposed to the surface of the base substrate 2.

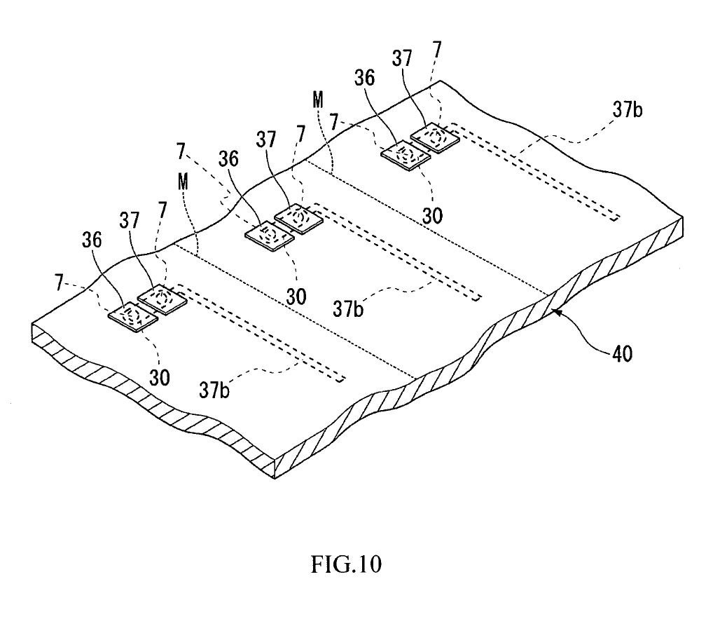

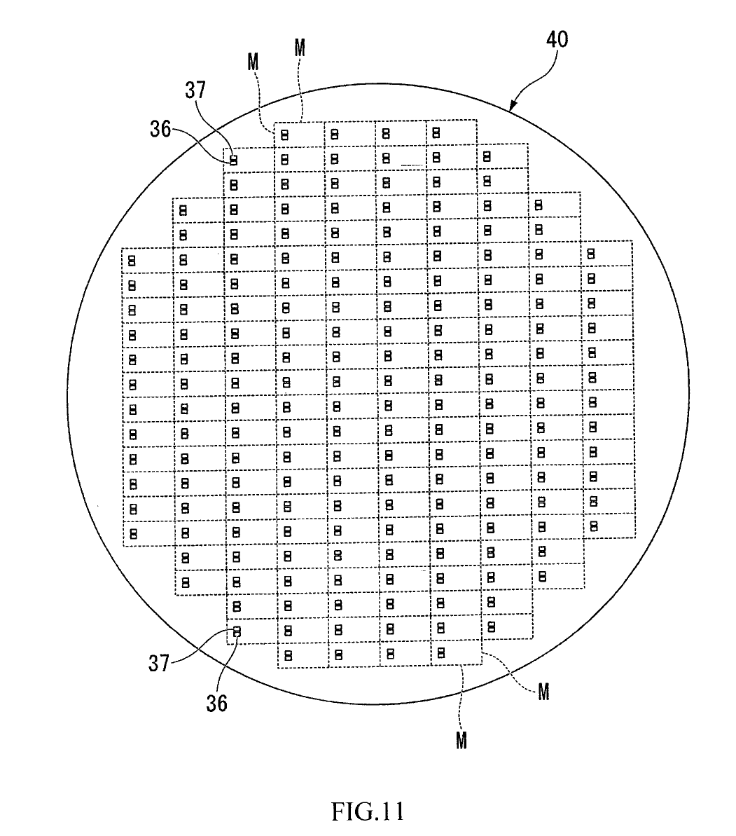

Next, as shown in FIG. 10 and FIG. 11, a routing electrode forming step (S33) is performed in which a conductive material is patterned on the inner face of the wafer for base substrate 40 to form the routing electrodes 36 and 37. The routing electrodes 36 and 37 are electrically connected to the through electrodes 7 and 7, respectively. Dotted lines M shown in FIG. 10 and FIG. 11 are cutting lines imaginarily showing lines on which cutting is performed at a cutting step performed later.

At this point, the base substrate wafer producing step (S30) is ended.

After the base substrate wafer producing step (S30), a mount step (piezoelectric vibrating strip mounting step) (S40) is performed. The mount step is a step of electrically connecting the piezoelectric vibrating strip 4 to the routing electrodes 36 and 37 so that the piezoelectric vibrating strip 4 is housed within the cavity C at an overlaying step, later described.

In the present embodiment, each of the plurality of piezoelectric vibrating strips 4 produced is mounted on the inner face side of the wafer for base substrate 40 through the bump B. This electrically connects the mount electrodes 16 and 17 of the piezoelectric vibrating strip 4 to the routing electrodes 36 and 37.

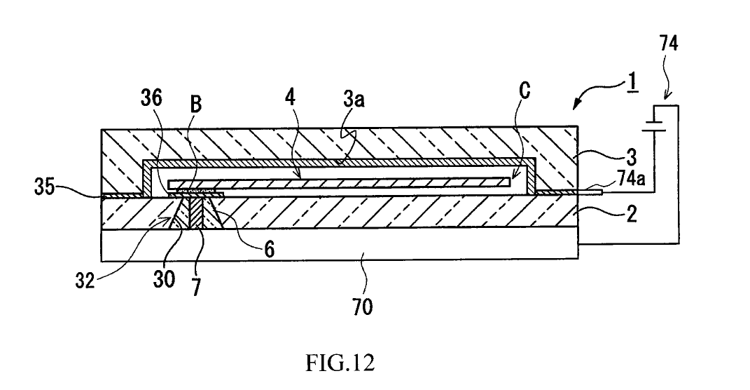

Next, as shown in FIG. 12, a placement step (S50) is performed in which the inner face of the wafer for lid substrate 50 is put on the inner face of the wafer for base substrate 40 to place the outer face of the wafer for base substrate 40 on an electrode pedestal 70 for anodic bonding.

First, the electrode pedestal 70 for anodic bonding is described. As shown in FIG. 12, the electrode pedestal 70 represents one electrode functioning as a negative terminal of a pair of electrodes included by voltage applying means 74 for anodic bonding provided within an anodic-bonding device, not shown. In the example shown, the other electrode functioning as a positive terminal of the pair of electrodes is an electrode 74a electrically connected to the bonding film 35.

The electrode pedestal 70 is a conductive plate-shaped member formed to have a size equal to or larger than the wafer for base substrate 40, and is made of stainless steel (SUS) or the like, for example.

Next, the placement step (S50) is described in detail.

First, as shown in FIG. 12, the overlaying step (S51) is performed in which the wafer for lid substrate 50 is put on the wafer for base substrate 40. Since the overlaying step is performed in wafers, a plurality of lid substrates 3 are overlaid on a plurality of base substrates 2 actually at a time. For convenience, however, FIG. 12 shows the single lid substrate 3 overlaid on the base substrate 2.

In performing the overlaying step, the wafers 40 and 50 are aligned at correct positions by using a reference mark or the like, not shown, as an indicator. This allows the piezoelectric vibrating strip 4 mounted on the wafer for base substrate 40 to be housed in the cavity C surrounded by the wafers 40 and 50.

Next, a set step (S52) is performed in which the wafers 40 and 50 placed one on another are put into an anodic-bonding device, not shown, and the wafer for base substrate 40 is put (placed) on the electrode pedestal 70. At the set step, the electrode 74a of the voltage applying means 74 is electrically connected to the bonding film 35.

The placement step is thus be ended.

Next, an anodic-bonding step (S55) is performed in which a bonding voltage (600 V to 800 V) is applied to the bonding film 35 and the electrode pedestal 70 to anodic-bond the wafer for lid substrate 50 to the wafer for base substrate 40 while heating is performed to a bonding temperature.

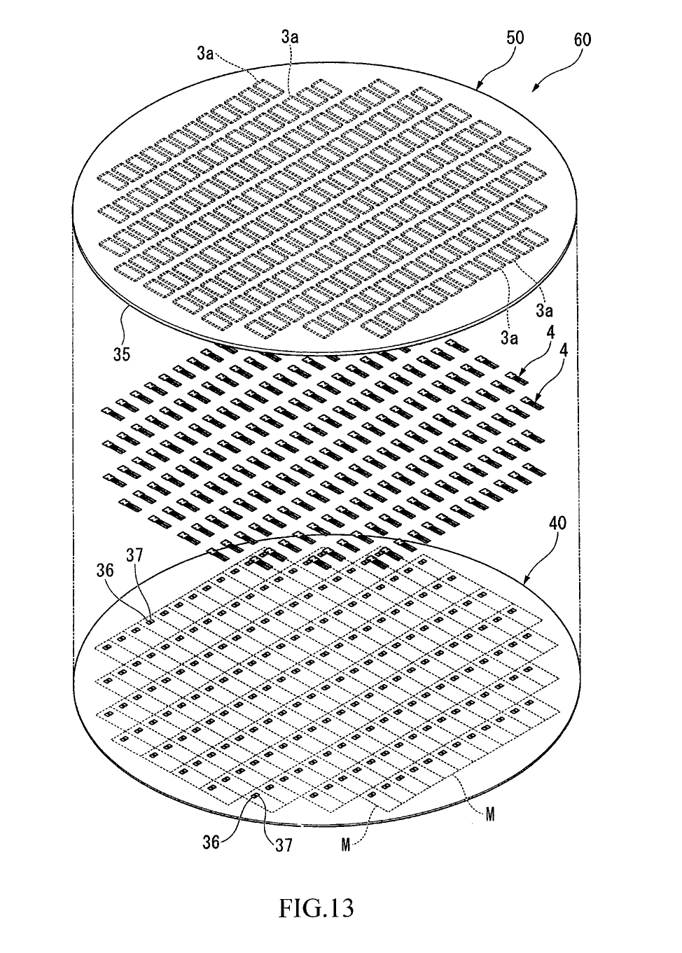

After the anodic bonding is completed, the piezoelectric vibrating strip 4 is enclosed in the cavity C, and the wafer unit 60 is obtained as shown in FIG. 13 in which the wafer for base substrate 40 is bonded to the wafer for lid substrate 50. Dotted lines shown in FIG. 13 are cutting lines on which cutting is performed at the cutting step, later described.

After the anodic-bonding step is ended, an external electrode forming step (S60) is performed.

At the external electrode forming step, a conductive material is patterned on the outer face of the wafer for base substrate 40 to form the pair of external electrodes 38 and 39 electrically connected to the pair of through electrodes 7 and 7.

As shown, one through electrode 7 is connected directly to the external electrode 38, while the other through electrode 7 is connected to the external electrode 38 through the external routing electrode 37b. The routing electrode 37b is also formed through patterning of a conductive material similarly to the external electrodes 38 and 39. With the configuration described above, a voltage can be applied to the external electrodes 38 and 39 to operate the piezoelectric vibrating strip 4 enclosed within the cavity C.

Next, a fine adjustment step (S70) is performed in which the frequency of each piezoelectric vibrating strip 4 enclosed within the cavity C is fine adjusted to fall within a predetermined range. First, a voltage is applied to the external electrodes 38 and 39 to vibrate the piezoelectric vibrating strip 4. While measuring the frequency, laser light is applied from the outside through the wafer for base substrate 40 to evaporate the fine adjustment film 21b of the weight metal film 21. This can change the weight of the pair of the vibrating arm portions 10 and 11 on the tip side to perform the fine adjustment such that the frequency of the piezoelectric vibrating strip 4 falls within the predetermined range of nominal frequencies.

The fine adjustment step (S70) may be performed after the cutting step (S80), later described. Specifically, the fine adjustment step may be performed on the wafer unit 60, or after the wafer unit 60 is singulated into individual piezoelectric vibrators 1, the fine adjustment step may be performed on the individual piezoelectric vibrators 1. In terms of productivity, the fine adjustment step is desirably performed on the wafer unit 60.

After the completion of the fine adjustment step, the cutting step (S80) is performed in which the bonded wafer unit 60 is cut along the cutting lines M shown in FIG. 13 into small strips.

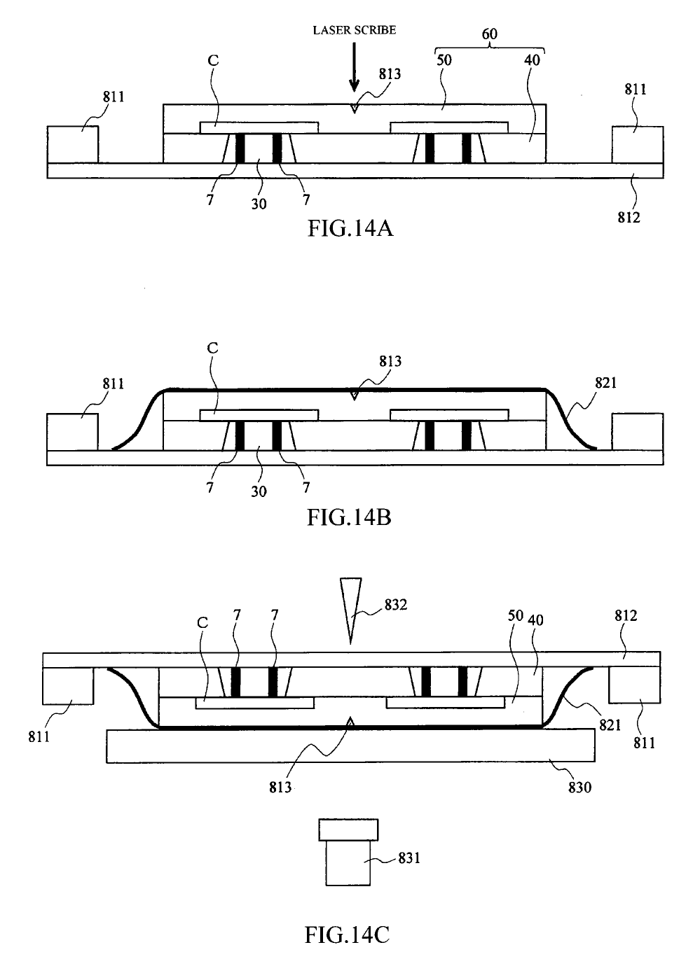

FIGS. 14A, 14B, and 14C show the cutting step. For clarity of the figure, FIGS. 14A, 14B, and 14C show part of the section of the two piezoelectric vibrators 1 placed in the lateral direction.

The cutting step includes the execution of a scribe step (S81) in which microgrooves are formed along the cutting lines M, a separator attaching step (S82) in which a separator is attached to the surface having the microgrooves formed therein, and a break step (S83) in which the wafer unit 60 is pressed along the microgrooves from the opposite side to the microgrooves to cut the wafer unit 60. In the following, each of the steps is described.

### (a) Scribe Step (S81)

At the scribe step, as shown in FIG. 14A, the wafer unit 60 is affixed to an adhesion face of a UV tape affixed to one face of a ring 811. In this case, the side of the wafer for base substrate 40 is affixed to the UV tape, and the side of the wafer for lid substrate 50 is closer to a notch.

Next, the cutting point is determined on the basis of an image taken by a camera, not shown. The cutting point may be the center of the anodic-bonded portion. Since the portion of the cavity C appears in bright color and the anodic-bonded portion appears in dark color in the image on the side of the wafer for lid substrate 50, the center of the portion appearing in dark color in the image may be determined as the cutting point.

The laser light is applied along the cutting lines M while the cutting point is checked, thereby forming the microgrooves 813 on the upper face of the wafer for lid substrate 50. The width of the groove formed by the laser is approximately 10 μm (±3 The microgroove 813 is formed over the entire wafer unit 60.

While the cutting point is determined by using the dark and bright portions of the image in the present embodiment, the cutting point may be determined with the distance from a predetermined reference point formed on the wafer unit 60.

The microgroove 813 may be formed on the side of the wafer for base substrate 40. In this case, the wafer unit 60 is cut by pressing the side of the wafer for lid substrate 50 which is the opposite side to the microgroove 813 at the break step, later described.

### (b) Separator Attaching Step (S82)

At the separator attaching step, to first remove shavings produced in forming the microgroove 813 at the scribe step, the surface of the wafer for lid substrate 50 is cleaned and dried. The shavings may be removed by blowing air.

After the surface of the wafer for lid substrate 50 is cleaned, a transparent separator 821 having elasticity is affixed to cover the entire face of the wafer for lid substrate 50 in which the microgroove 813 is formed. While a UV tape is used for the separator 821, another tape having adherence may be used.

### (c) Break Step (S83)

Next, the wafer unit 60 is turned upside down and placed on a transparent rubber 830. Specifically, the wafer unit 60 is placed on the transparent rubber 830 with the separator 821 affixed to the wafer for lid substrate 50 located on the lower side and the UV tape 812 affixed to the wafer for base substrate 40 located on the upper side.

The transparent rubber 830 is made of a material functioning as a cushion when the wafer unit 60 is pressed, for example silicon. The use of the transparent rubber 830 allows a camera 831 to recognize the microgroove 813 formed in the wafer for lid substrate 50.

Next, an image of the wafer for lid substrate 50 is taken by the camera 831 from below the transparent rubber 830. The microgroove 813 is detected from the image, and the pressing blade 832 is moved to the position on the opposite side to the detected microgroove 813 to perform positioning.

Then, the pressing blade 832 is gradually lowered to press the wafer for base substrate 40 from the opposite side to the microgroove 813. This bends the wafer unit 60 at the pressing blade 832 in contact with the wafer for base substrate 40, so that the wafer unit 60 can be split along the microgroove 813 with the laser.

Since the pressing blade 832 used in this case has a blade length larger than the maximum diameter of the wafer unit 60, the wafer unit 60 can be split only by pressing the pressing blade 832 once.

Since the UV tape 812 and the separator 821 are affixed to both side faces of the wafer unit 60, the glass strips can be prevented from scattering during the splitting.

While the wafer unit 60 is deformed at the splitting, the separator has the elasticity and thus is not broken.

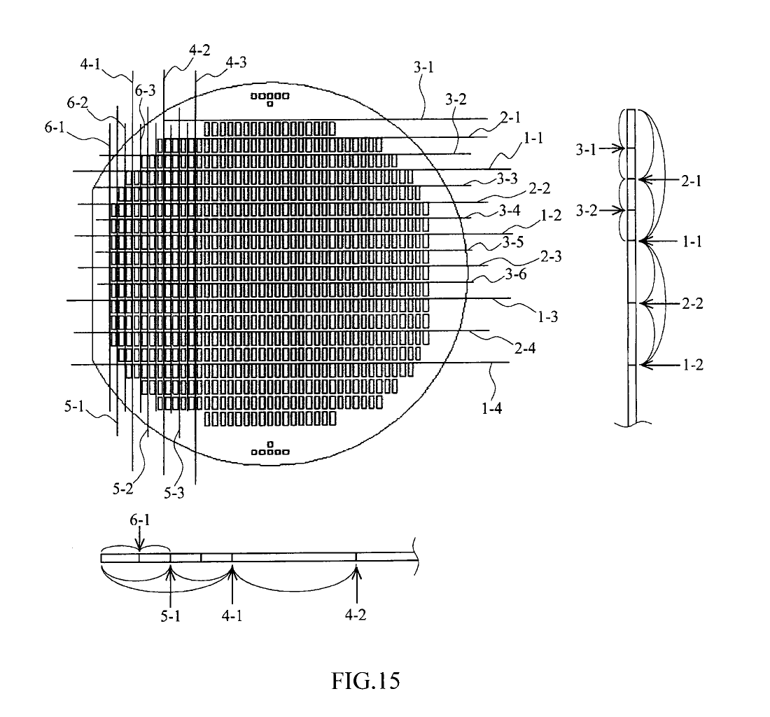

Next, the order of performing the break step S83 is described with reference to FIG. 15.

The break step S83 is first performed along the lateral direction of the piezoelectric vibrator 1. After the cutting in the lateral direction is ended, the wafer unit 60 is rotated 90 degrees and cut along the longitudinal direction of the piezoelectric vibrator 1. This completes the splitting of the piezoelectric vibrator 1.

Either of the cutting in the lateral direction and the cutting in the longitudinal direction of the piezoelectric vibrator 1 may be first performed, and the cutting may be performed in the order in which the piezoelectric vibrator 1 is not easily deformed.

Next, description is made of which cutting line M is first used in the cutting of the wafer unit 60 in the lateral direction of the piezoelectric vibrator 1. In this case, the order of cutting may be selected such that the pressing blade 832 applies a pressure on the wafer unit 60 as uniformly as possible over the entire wafer unit 60.

Specifically, the wafer unit 60 may be cut in order every four cutting lines M from the end. As shown in FIG. 15, the wafer unit 60 may be cut in order of 1-1, 1-2, 1-3, etc. In this case, since the width of the piezoelectric vibrator 1 for at least four columns are left, the pressure applied to the wafer unit 60 by the pressing blade 832 can be distributed as much as possible. While the wafer unit 60 is cut every four cutting lines M in this case, another cutting method may be selected as long as the pressure is applied to the wafer unit 60 as uniformly as possible.

After the wafer unit 60 is cut into sets of four columns, the wafer unit 60 is cut into sets of two columns on the left and right. Specifically, the wafer unit 60 is cut in order of 2-1, 2-2, 2-3, etc. in FIG. 15. While the order is not limited thereto in the cutting at the second stage since all are set of four columns, the cutting is performed in order from the end in view of the work efficiency.

Then, the wafer unit 60 is cut on the microgroove 813 at the center of the two columns. Specifically, the cutting is performed in order of 3-1, 3-2, 3-3, etc., in FIG. 15.

The order of cutting the wafer unit 60 is not limited thereto, and an appropriate cutting method may be selected in view of the work efficiency, the yields, and the like.

After the cutting in the lateral direction of the piezoelectric vibrator 1, the cutting in the longitudinal direction is performed. For the cutting in the longitudinal direction, an appropriate cutting method may be selected in view of the work efficiency, the yields, and the like similarly to the cutting in the lateral direction.

Since the wafer unit 60 is adhesively fixed with the UV tape 812 and the separator 821 even at the time of the completion of the cutting in the lateral direction, the wafer unit 60 is not displaced.

FIG. 15 shows the cutting order in the longitudinal direction. Specifically, the cutting is first performed in order of 4-1, 4-2, . . . , and then the cutting is performed in order of 5-1, 5-2, . . . , and finally the cutting is performed in order of 6-1, 6-2, . . . .

After the entire wafer unit 60 is cut and split into the individual piezoelectric vibrators 1, ultraviolet lays (UV) are applied to the UV tape 812 to strip the UV tape from each of the piezoelectric vibrators 1. Then, the piezoelectric vibrator 1 is removed from the separator 821.

At the cutting step (S80), the external electrodes 38 and 39 may be cut together with the wafer unit 60 in pressing with the pressing blade 832. To avoid this, the external electrodes 38 and 39 may be patterned so as to avoid the area corresponding to the cutting lines M.

Through these steps, the plurality of piezoelectric vibrators 1 of the surface mount type can be manufactured at a time.

Then, an internal electric characteristic test (S90) is performed. Specifically, the resonance frequency, the resonance resistance value, the vibration characteristics and the like of the piezoelectric vibrating strip 4 are checked. Finally, the outer appearance test of the piezoelectric vibrator 1 is performed to check the quality and the like finally. Thus, the manufacturing of the piezoelectric vibrator 1 is finished.

As described above, in the method of manufacturing the piezoelectric vibrator 1 according to the present embodiment, the microgroove 813 is formed by the laser in one face of the wafer unit 60 and the pressing blade 832 is pressed against the other face of the wafer unit 60 to split the wafer unit 60 into the plurality of piezoelectric vibrators 1, so that the following effects can be provided.

### <Effect 1>

Conventionally, a blade is passed through the wafer unit 60 to split the wafer 60 into a plurality of piezoelectric vibrators 1. Thus, a cutting margin (approximately 150 μm to 200 μm) corresponding to at least the blade width is required on the surface of the wafer unit 60. In contrast, the present embodiment employs the method of “pressing and splitting” the wafer unit 60 along the microgroove (approximately 10 μm±3 μm) with the laser, so that the cutting margin can be reduced in size as compared with the conventional one.

### <Effect 2>

As compared with the case where the blade is used to cut the wafer unit 60 as conventional, the impact to the wafer unit 60 can be reduced during the cutting.

### <Effect 3>

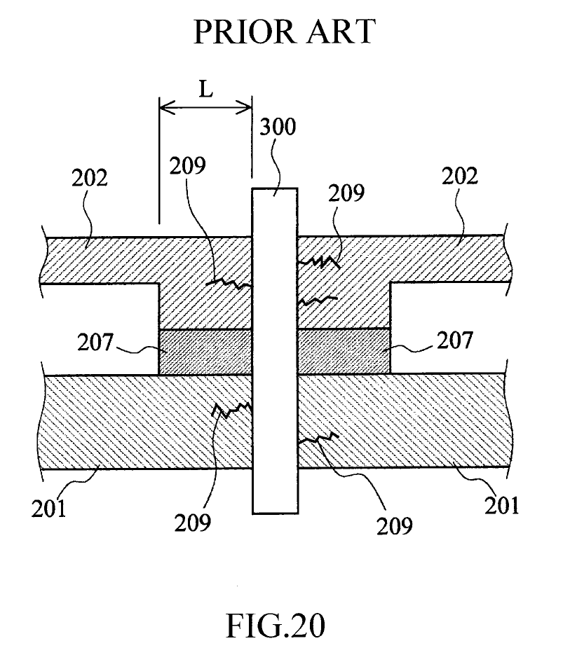

In addition, the width of the bonding face of the base substrate 2 and the lid substrate 3 can be reduced in association with the abovementioned Effect (2). Specifically, as shown in FIG. 20 and FIG. 2, the bonding width L of 200 μm or more is conventionally required for the base substrate 2 and the lid substrate 3 so as to endure the impact during the cutting. In the present embodiment, however, the impact in the cutting is reduced, so that the bonding width of the base substrate 2 and the lid substrate 3 can be reduced to 100 μm to 150 μm. This can reduce the size of the piezoelectric vibrator 1.

### <Effect 4>

Since the “cutting margin” and the “bonding width” are reduced as described above, more piezoelectric vibrators 1 can be obtained at a time from the wafer unit 60. In addition, the wafer for base substrate 40 and the wafer for lid substrate 50 can be reduced in size.

The pair of through electrodes 7 and 7 is placed within the single through hole in the present embodiment. Thus, the number of the through holes can be reduced as compared with the case where the single through electrode 7 is provided for each of the two through holes, so that the strength of the piezoelectric vibrator 1 can be enhanced.

### (6) Oscillator

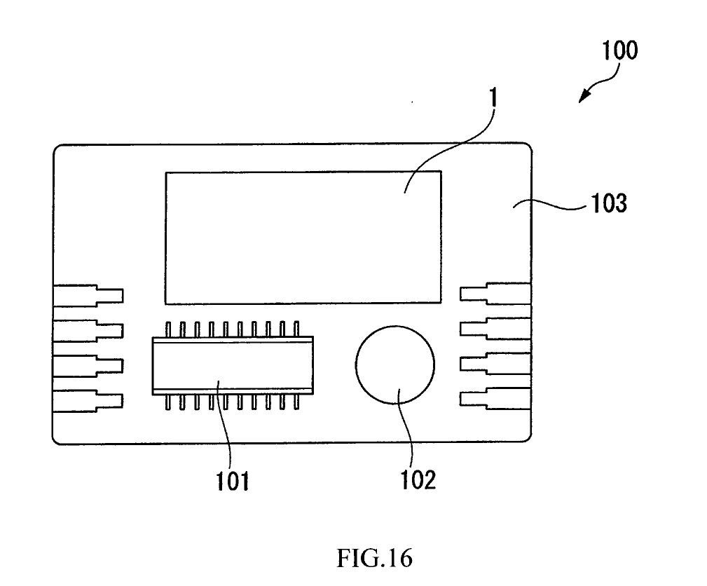

Next, an embodiment of the oscillator according to the present embodiment is described with reference to FIG. 16.

As shown in FIG. 16, an oscillator 100 of the present embodiment employs the piezoelectric vibrator 1 as an oscillating element electrically connected to an integrated circuit 101. The oscillator 100 includes a substrate 103 on which an electronic part 102 such as a capacitor is mounted. The integrated circuit 101 is mounted on the substrate 103, and the piezoelectric vibrator 1 is mounted near the integrated circuit 101. The electronic part 102, the integrated circuit 101, and the piezoelectric vibrator 1 are electrically connected through a wiring pattern, not shown. Each of the components is molded from resin.

When a voltage is applied to the piezoelectric vibrator 1 in the oscillator 100 thus formed, the piezoelectric vibrating strip 4 vibrates within the piezoelectric vibrator 1. The vibration is converted into an electric signal with the piezoelectric characteristics of the piezoelectric vibrating strip 4 and is input as the electric signal to the integrated circuit 101. The input electric signal is subjected to various types of processing by the integrated circuit 101 and is output as a frequency signal. The piezoelectric vibrator 1 functions as the oscillating element in this manner.

The configuration of the integrated circuit 101 can be selectively set for an RTC (Real Time Clock) module or the like as required to add the function of providing the time or calendar.

Since the piezoelectric vibrator 1 with higher quality is included in the present embodiment, the oscillator 100 can be provided with higher quality.

### (7) Electronic Device

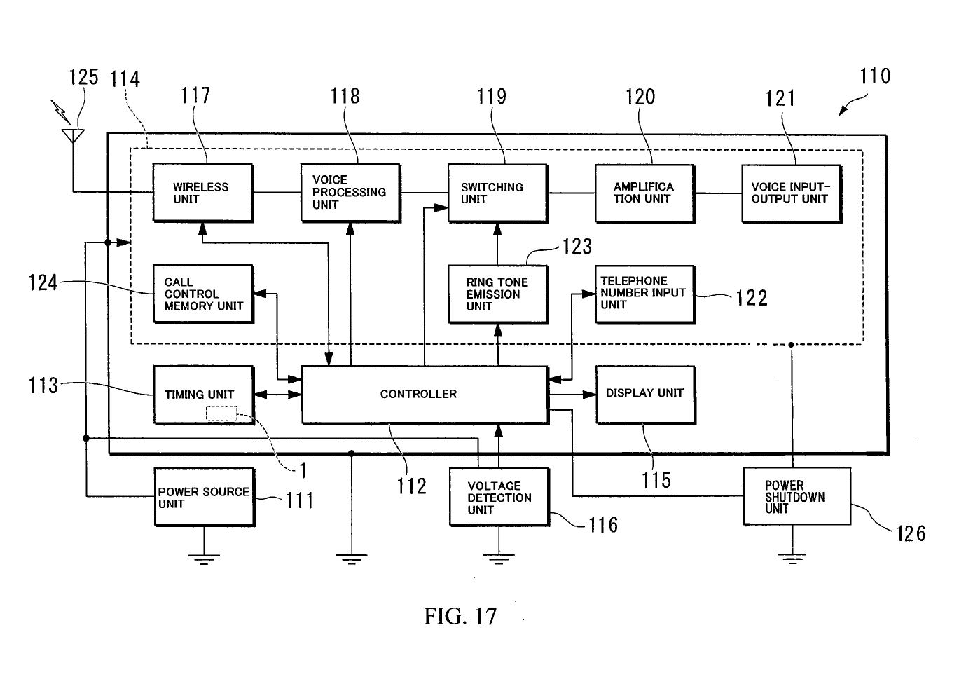

Next, an embodiment of the electronic device according to the present embodiment is described with reference to FIG. 17. The description is made by using a portable information device 110 having the piezoelectric vibrator 1 described above as an example of the electronic device. Examples of the portable information device 110 include a cellular phone and a small communication device.

Next, the configuration of the portable information device 110 of the present embodiment is described. The portable information device 110 includes the piezoelectric vibrator 1 and a power source section 111 for supplying power. The power source section 111 is formed of a lithium secondary battery, for example. The power source section 111 is connected to a control section 112 for performing various types of controlling, a timer section 113 for counting time or the like, a communication section 114 for performing communication with the outside, a display section 115 for displaying various types of information, and a voltage detecting section 116 for detecting the voltage of each functioning portion. The power source section 111 supplies the power to each functioning portion.

The control section 112 performs the control of operation of the overall system by controlling each functioning portion to perform transmission and reception of voice data, counting and display of the present time, and the like. The control section 112 includes a ROM having a previously written program, a CPU reading and executing the program written to the ROM, a RAM used as a work area for the CPU, and the like.

The timer section 113 includes an integrated circuit containing an oscillating circuit, a register circuit, a counter circuit, an interface circuit and the like, and the piezoelectric vibrator 1. When a voltage is applied to the piezoelectric vibrator 1, the piezoelectric vibrating strip 4 vibrates, and the vibration is converted into an electric signal with the piezoelectric characteristics of the crystal and is input as the electric signal to the oscillating circuit.

The communication portion 114 has the function similar to a conventional cellular phone, and includes a radio section 117, a voice processing section 118, a switch section 119, an amplifying section 120, a voice input/output section 121, a telephone number input section 122, a ringing sound generating section 123, and a call control memory section 124.

The radio section 117 transmits and receives various types of data such as voice data to and from a base station through an antenna 125. The voice processing section 118 encodes and decodes a voice signal input from the radio section 117 or the amplifying section 120. The amplifying section 120 amplifies the signal input from the voice processing section 118 or the voice input/output section 121 to a predetermined level. The voice input/output section 121 is formed of a speaker, a microphone or the like, and turns up the volume of a ringing sound or a received voice or gathers voice.

The ringing sound generating section 123 produces the ringing sound in response to calling from the base station. The switch section 119 switches the amplifying section 120 connected to the voice processing section 118 to the ringing sound generating section 123 only in reception of a call to output the ringing sound produced in the ringing sound generating section 123 to the voice input/output section 121 through the amplifying section 120.

The call control memory section 124 stores a program relating to control of call origination/reception in communication. The telephone number input section 122 includes numeric keys from zero to nine and other keys, for example, and a user presses these numeric keys or the like to input a telephone number of a called party.

The voltage detecting section 116 detects a drop of a voltage applied by the power source section 111 to each functioning portion such as the control section 112 to below a predetermined value and notifies the control section 112 of the voltage drop. The predetermined voltage in this case is a preset value as the minimum voltage required for stably operating the communication section 114, and for example, approximately 3 V. Upon notification of the voltage drop from the voltage detecting section 116, the control section 112 inhibits the operation of the radio section 117, the voice processing section 118, the switch section 119, and the ringing sound generating section 123. Especially, the stop of the operation is essential in the radio section 117 which requires significant power consumption. In addition, the display section 115 displays the fact that the communication section 114 is unusable due to battery exhaustion.

Specifically, the voltage detecting section 116 and the control section 112 can inhibit the operation of the communication section 114 and that fact can be displayed on the display section 115. The display may be a text message, or may be an “X” mark as a more intuitive display put to a telephone icon displayed in an upper portion of a display face of the display section 115.

A power source shutoff portion 126 capable of selectively shutting off the power source of the portion relating to the function of the communication section 114 can be provided to stop the function of the communication section 114 more reliably.

Since the piezoelectric vibrator 1 with higher quality is included in the present embodiment, the portable information device 110 can be improved in quality.

### (7) Radio Watch

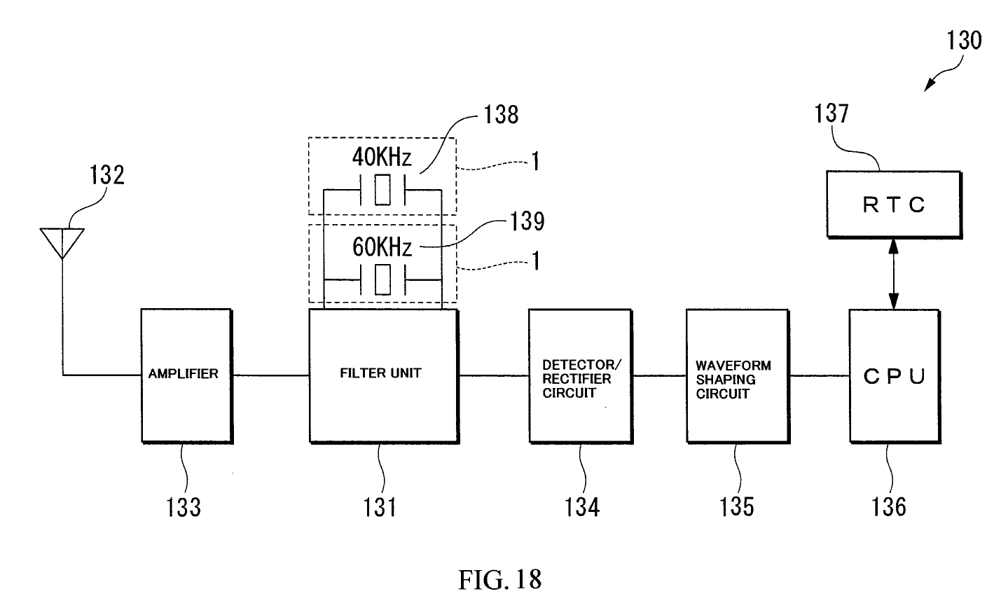

Next, an embodiment of the radio watch according to the present invention is described with reference to FIG. 18. The radio watch 130 of the present embodiment includes the piezoelectric vibrator 1 electrically connected to a filter section 131, and has the function of receiving standard radio waves including watch information to perform automatic correction to a correct time and display thereof.

There are transmission stations for transmitting standard radio waves in Fukushima prefecture (40 kHz) and Saga prefecture (60 kHz) in Japan. Since a long wave such as 40 kHz and 60 kHz has both of the nature of propagating on the ground surface and the nature of propagating while reflecting in the ionosphere and the ground surface, the long wave propagates over a wide range, and the abovementioned two transmission stations cover all Japan.

In the following, the functional configuration of the radio watch 130 is described in detail.

An antenna 132 receives the long-wave standard radio wave of 40 kHz or 60 kHz. The long-wave standard radio wave is provided by amplitude modulation of a carrier wave of 40 kHz or 60 kHz with time information called time code. The received long wave standard radio wave is amplified by an amplifier 133 and filtered and tuned by the filter section 131 having a plurality of piezoelectric vibrators 1. The piezoelectric vibrator 1 in the present embodiment includes crystal vibrating sections (piezoelectric vibrating strips) 138 and 139 having resonance frequencies of 40 kHz and 60 kHz identical to the abovementioned carrier frequencies.

In addition, the filtered signal at the predetermined frequency is detected and demodulated by a detection and rectification circuit 134. Then, the time code is taken through a waveform shaping circuit 135 and is counted by a CPU 136. The CPU 136 reads information such as the current year, accumulated days, day of week, and time. The read information is reflected in an RTC 137 and accurate time information is displayed.

While the above description has shown the example in Japan, a standard radio wave of 77.5 kHz is used in Germany, by way of example. Thus, for incorporating the radio watch 130 usable overseas into a portable device, the piezoelectric vibrator 1 with a frequency different from that in Japan is required.

Since the piezoelectric vibrator 1 with higher quality is included in the present embodiment, the radio watch 130 can be improved in quality.

The technical scope of the present invention is not limited to the embodiment described above, and various modifications can be made without departing from the spirit or scope of the present invention.

For example, while the above embodiment has been described with the example of the grooved piezoelectric vibrating strip 4 having the groove portion 18 on both faces of the vibrating arm portions 10 and 11 as an example of the piezoelectric vibrating strip 4, the piezoelectric vibrating strip may be of a type including no groove portion 18.

While the above embodiment has been described with the example of the tuning fork-type crystal vibrator as the piezoelectric vibrator, another piezoelectric vibrator can be used, for example an AT vibrator, and a coupled vibrator having a plurality of vibration modes coupled.

The above embodiment has described the example in which the method of manufacturing the package according to the present invention is applied to the method of manufacturing the piezoelectric vibrator for manufacturing the piezoelectric vibrator 1 housing the piezoelectric vibrating strip 4 on the routing electrodes 36 and 37 within the cavity C of the package 9. However, the present invention is applicable to manufacture of a configuration in which the routing electrodes 36 and 37 are electrically connected to wiring different from the piezoelectric vibrating strip 4.

What is claimed is:

1. A method for manufacturing a plurality of piezoelectric vibrators, the method comprising:
mounting a plurality of piezoelectric vibrating strips on a first wafer;
bonding the first wafer and a second wafer together to form a wafer unit;
forming a plurality of microgrooves along cutting lines on a first outer surface of the wafer unit, wherein the cutting lines include cutting lines extending in a first direction and cutting lines extending in a second direction that is perpendicular to the first direction; and
applying pressure to a second outer surface of the wafer unit that is opposite to the first outer surface to split the wafer unit along the microgrooves into the piezoelectric vibrators.

2. The method of claim 1, wherein forming the plurality of microgrooves comprises irradiating the first outer surface with a laser along the cutting lines.

3. The method of claim 1, wherein the pressure is applied by pushing the second outer surface of the wafer unit with a pressing blade that is at least as wide as a diameter of the wafer unit.

4. The method of claim 1, wherein a width of each microgroove is about 10 μm.

5. The method of claim 1, wherein a width of each microgroove is between 7 μm and 13 μm.

6. The method of claim 1, wherein the first outer surface of the wafer unit on which the plurality of microgrooves is formed corresponds to a side of the first wafer that is opposite to a side of the first wafer bonded to the second wafer.

7. The method of claim 6, wherein the pressure is applied to a side of the second wafer that is opposite to a side of the second wafer bonded to the first wafer.

8. The method of claim 1, further comprising covering the first outer surface of the wafer unit with a transparent elastic material.

9. The method of claim 8, further comprising placing wafer unit on a transparent rubber such that the first outer surface covered by the transparent elastic material is facing the transparent rubber.

10. The method of claim 9, further comprising detecting the location of the microgrooves in the first outer surface.

11. The method of claim 10, wherein the pressure is applied to the second outer surface of the wafer unit at a line opposite to a cutting line in the first outer surface that corresponds to the detected microgrooves.

12. The method of claim 11, wherein the pressure is applied by pushing the second outer surface of the wafer unit with a pressing blade that is at least as wide as a diameter of the wafer unit.

13. A method for manufacturing a plurality of piezoelectric vibrators provided within a wafer unit that comprises a first wafer and a second wafer bonded together, the method comprising:
forming a plurality of microgrooves along cutting lines on a first outer surface of the wafer unit, wherein the cutting lines include cutting lines extending in a first direction and cutting lines extending in a second direction that is perpendicular to the first direction; and
applying pressure to a second outer surface of the wafer unit that is opposite to the first outer surface to split the wafer unit along the microgrooves into the piezoelectric vibrators.

14. The method of claim 13, wherein forming the plurality of microgrooves comprises irradiating the first outer surface with a laser along the cutting lines.

15. The method of claim 13, wherein the pressure is applied by pushing the second outer surface of the wafer unit with a pressing blade that is at least as wide as a diameter of the wafer unit.

16. The method of claim 13, further comprising detecting the location of the microgrooves in the first outer surface using a camera.

17. The method of claim 16, wherein applying the pressure comprises pressing a blade having a width at least as wide as a diameter of the wafer unit along a line on the second outer surface that is opposite to a first cutting line on the first outer surface that includes the detected microgrooves, causing the wafer unit to separate along the first cutting line.

18. The method of claim 17, further comprising successively pressing the blade along different lines on the second outer surface to sequentially separate the wafer unit along sequential cutting lines in the first outer surface.

19. A wafer unit comprising:
a first wafer comprising a first side and a second side having embedded thereon multiple piezoelectric vibrating strips;
a second wafer comprising a first side and a second side bonded to the second side of the first wafer; and
multiple microgrooves formed along cutting lines in one of the first side of the first wafer or the first side of the second wafer, wherein the cutting lines include cutting lines extending in a first direction and cutting lines extending in a second direction that is perpendicular to the first direction such that a cutting line extends between adjacent pairs of piezoelectric vibrating strips.

20. The wafer unit of claim 19, where the multiple microgrooves are formed along cutting lines in the first side of the first wafer.
